(19) United States
(12) Patent Application Publication
(10) Pub. No.: US 2024/0005070 A1
(43) Pub. Date: Jan. 4, 2024

(54) INFERENCE DEVICE AND INFERENCE METHOD

(71) Applicant: Preferred Networks, Inc., Tokyo (JP)

(72) Inventor: Akihide HAYASHI, Tokyo (JP)

(73) Assignee: Preferred Networks, Inc., Tokyo (JP)

(21) Appl. No.: 18/343,462

(22) Filed: Jun. 28, 2023

(30) Foreign Application Priority Data
Jun. 30, 2022 (JP) 2022-105666

(51) Int. Cl. G06F 30/27

(52) U.S. Cl. CPC G06F 30/27; G06F 2119/14

(57) ABSTRACT

According to one embodiment, an inference device includes at least one memory and at least one processor. The at least one processor performs a computation for geometry optimization of a substance by a first algorithm. After a predetermined condition is satisfied, the at least one processor performs, based on a result of the computation by the first algorithm, a geometry optimization of the substance by a second algorithm different from the first algorithm.

### CROSS-REFERENCE TO RELATED APPLICATIONS

This application is based upon and claims the benefit of priority from Japanese Patent Application No. 2022-105666, filed on Jun. 30, 2022; the entire contents of which are incorporated herein by reference.

### BACKGROUND OF THE INVENTION

### 1. Field of the Invention

Embodiments described herein relate generally to an inference device and an inference method.

### 2. Description of the Related Art

In geometry optimization of a substance composed of multi-bodied atomic nuclei and electrons, an initial structure may be obtained by a given approximate computation to compute a structure with minimum energy based on the resultant initial structure.

However, such a traditional geometry optimization process may be disadvantageous in terms of rate of convergence and robustness.

### SUMMARY OF THE INVENTION

According to one aspect of an embodiment of the invention, an inference device comprises at least one memory and at least one processor. The at least one processor is configured to perform a computation for geometry optimization of a substance by a first algorithm, and, after a predetermined condition is satisfied, perform, based on a result of the computation by the first algorithm, a geometry optimization of the substance by a second algorithm different from the first algorithm.

### BRIEF DESCRIPTION OF THE DRAWINGS

FIG. 1 is a block diagram illustrating an exemplary hardware configuration of an inference device according to an embodiment;

FIG. 2 illustrates an example of functional blocks in a processor according to an embodiment;

FIG. 3 is a flowchart illustrating an exemplary inference process to be performed by an inference device according to a first embodiment;

FIG. 4 is a flowchart illustrating an exemplary inference process to be performed by an inference device according to a second embodiment;

FIG. 5 is a flowchart illustrating an exemplary inference process to be performed by an inference device according to a third embodiment; and

FIG. 6 is a flowchart illustrating an exemplary inference process to be performed by an inference device according to a fourth embodiment.

### DETAILED DESCRIPTION OF THE PREFERRED EMBODIMENTS

Hereinafter, various embodiments of an inference device will be described in detail with reference to the accompanying drawings. The following embodiments are presented for illustrative purpose only and not intended to limit the scope of the present invention.

### First Embodiment

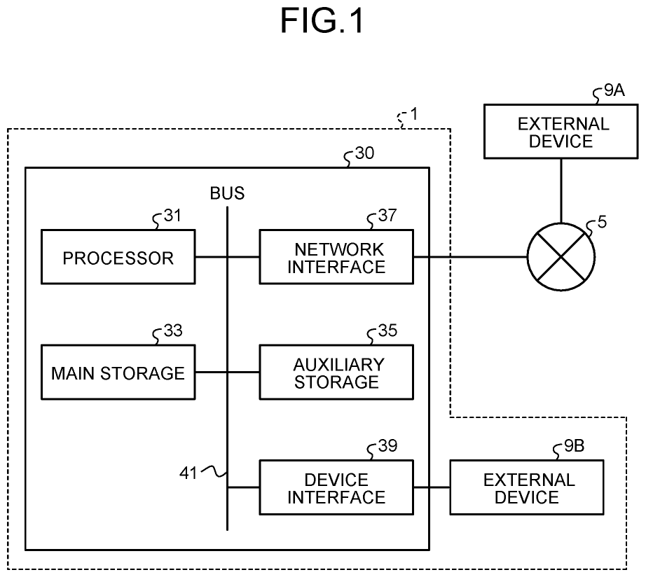

FIG. 1 is a block diagram illustrating an exemplary hardware configuration of an inference device 1 according to a first embodiment. As illustrated in FIG. 1, the inference device 1 may be connected to an external device 9A via a communication network 5. Alternatively, the inference device 1 may include an external device 9B connected via a device interface 39.

The inference device 1 may receive positional information (three-dimensional coordinates) of multiple atoms included in a substance and output energy of the three-dimensional molecular structure of the substance. Such a substance is not limited to molecules and may be any of various kinds of crystals, for example.

Further, the inference device 1 may iteratively compute for geometry optimization of the substance based on the positional information of each atom of the substance and the energy of the substance. The inference device 1 may output the energy of a three-dimensional, minimum structure of the substance based on the positional information of each atom of the substance obtained through the geometry optimization process. In addition, the inference device 1 may use multiple algorithms in a switchable manner in the iterative computation of the geometry optimization process with respect to the substance, depending on a state such as an early phase or a final phase. The inference process, to be performed by the inference device 1, including the iterative computation for geometry optimization of the substance will be described in detail later.

The inference device 1 may include a computer 30 and the external device 9B connected to the computer 30 via the device interface 39. As an example, the computer 30 may include a processor 31, a main storage (memory) 33, an auxiliary storage (memory) 35, a network interface 37, and the device interface 39. Alternatively, the inference device 1 can be implemented as a computer 30 including the processor 31, the main storage 33, the auxiliary storage 35, the network interface 37, and the device interface 39 which are mutually connected via a bus 41.

Although the numbers of the respective elements in the computer 30 are all one in FIG. 1, the computer 30 may include two or more identical elements. Further, instead of the single computer 30 shown in FIG. 1, multiple software-installed computers may be provided to individually perform the same part or different parts of the software processing. In this case, distributed computing that the individual computers perform processing in parallel through mutual communications via the network interface 37 may be applied. In other words, the inference device 1 according to the present embodiment may be configured as a system including one or more storages and one or more computers to implement various kinds of functions as described later by the one or more computers' executing instructions stored in the one or more storages. Further, the inference device 1 may be configured such that one or more computers are provided on the cloud to receive and process information from terminals and transmit the results to a terminal, such as a display (display unit), corresponding to the external device 9B.

The inference device 1 according to the present embodiment may use one or more processors or two or more computers via a network to perform various kinds of computations in parallel. Alternatively, various kinds of computations may be allocated to the arithmetic cores of a processor to execute the computations in parallel. The processing, means, and else in this disclosure may be partially or entirely executed by at least either a processor or a storage provided on the cloud which is communicable with the computer 30 via a network. As such, various kinds of computations in the present embodiment, as described below, may be implemented by parallel computing with one or more computers.

The processor 31 may be electronic circuitry including the control unit and arithmetic unit of the computer 30, such as processing circuit, processing circuitry, central processing unit (CPU), graphics processing unit (GPU), field programmable gate array (FPGA), or application specific integrated circuit (ASIC). Alternatively, the processor 31 may be a semiconductor device including dedicated processing circuitry, for example. The processor 31 is not limited to electronic circuitry including electronic logic elements and may be implemented by optical circuitry including optical logic elements. The processor 31 may also be the one including a computational function based on quantum-computing.

The processor 31 can perform computation based on input data from the internal elements of the computer 30 or by software (computer program) and output results of the computation or control signals to the respective elements. The processor 31 may control the respective elements constituting the computer 30 by executing the operating system (OS) of the computer 30 and/or applications.

The inference device 1 of the present embodiment can be implemented by one or more processors 31. Herein, the processor 31 may refer to one or more electronic circuits disposed on a single chip, or to one or more electronic circuits disposed on two or more chips or two or more devices. If multiple electronic circuits are used, the electronic circuits may mutually communicate in a wireless or wired manner.

The main storage 33 stores therein commands to be executed by the processor 31, various kinds of data, and else. The processor 31 retrieves information from the main storage 33. The auxiliary storage 35 is storage other than the main storage 33. Such storages refer to freely selectable electronic components that can store electronic information, and can be semiconductor memories. The semiconductor memories can be either volatile or non-volatile. The storage for storing various kinds of data for use in the inference device 1 of the present embodiment can be implemented by the main storage 33 or the auxiliary storage 35, or by the internal memory embedded in the processor 31. In the present embodiment, for example, the storage unit may be implemented by the main storage 33 or the auxiliary storage 35.

The single processor 31 or multiple processors may be connected or coupled to a single storage (memory). Multiple storages (memories) may be connected or coupled to a single processor. The inference device 1 of the present embodiment may include at least one storage (memory) and multiple processors connected or coupled to the at least one storage (memory). In such a case, at least one of the processors may be connected or coupled to the at least one storage (memory). Alternatively, such an architecture can be implemented by the processor 31 and storages (memories) included in multiple computers. Further, an integration of a storage (memory) and the processor 31, such as a cache memory including L1 cache and L2 cache, may also be applicable.

The network interface 37 is an interface for connecting to the communication network 5 wirelessly or via wiring. The network interface 37 can be any suitable interface such as the one in compliance with an existing communication standard. The network interface 37 may allow the computer 30 to exchange information with the external device 9A connected via the communication network 5. The communication network 5 can be any suitable network as long as it allows the computer 30 and the external device 9A to mutually exchange information. For example, the communication network 5 can be any of wide area network (WAN), local area network (LAN), and personal area network (PAN), or any combination thereof. Examples of WAN include Internet. Examples of LAN include IEEE802.11 and Ethernet (registered trademark). Examples of PAN include Bluetooth (registered trademark) and near field communication (NFC).

The device interface 39 is an interface, such as a universal serial bus (USB), for directly connecting to an output device as a display, an input device, and the external device 9B. The output device may include a speaker that outputs audio, for example.

The external device 9A is connected to the computer 30 via the network while the external device 9B is directly connected to the computer 30.

The external device 9A or the external device 9B can be an input device (input unit) as an example. Examples of the input device include a camera, a microphone, a motion capture, various kinds of sensor, a keyboard, a mouse, and a touch panel. The external device 9A or the external device 9B provides the computer 30 with information as obtained. Also, the external device 9A or the external device 9B can be a device including an input, memory, and a processor, such as a personal computer, a tablet terminal, or a smartphone.

For another example, the external device 9A or the external device 9B can be an output device (output unit). Examples of the output device include a speaker that outputs audio, and a display (display unit) such as liquid crystal display (LCD), cathode ray tube (CRT), plasma display panel (PDP), or organic electro luminescence (EL) panel. Further, the external device 9A or the external device 9B can be a device including an output, memory, and a processor, such as a personal computer, a tablet terminal, or a smartphone.

The external device 9A or the external device 9B can be a storage (memory). For example, the external device 9A may be a network storage and the external device 9B may be a storage as HDD.

The external device 9A or the external device 9B can also be a device including part of the functions of the respective elements of the inference device 1 in the present embodiment. In other words, the computer 30 can transmit or receive all or part of results of the processing by the external device 9A or the external device 9B.

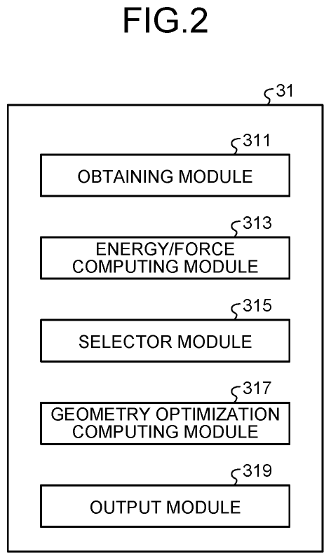

FIG. 2 illustrates the functional blocks in the processor 31 as an example. The processor 31 includes, for example, an obtaining module 311, an energy/force computing module 313, a selector module 315, a geometry optimization computing module 317, and an output module 319 as functions to be implemented by the processor 31. The functions to be implemented by the obtaining module 311, the energy/force computing module 313, the selector module 315, the geometry optimization computing module 317, and the output module 319 can be individually stored in the form of computer programs in, for example, the main storage 33 or the auxiliary storage 35. The processor 31 retrieves and executes the computer programs from the main storage 33 or the auxiliary storage 35 to be able to implement the functions related to the obtaining module 311, the energy/force computing module 313, the selector module 315, the geometry optimization computing module 317, and the output module 319.

The obtaining module 311 functions to obtain initial positional information (three-dimensional coordinates) of each atom of a substance of interest, in response to, for example, a user input. In addition, the obtaining module 311 may obtain positional information of each atom of the substance of interest as computed by the geometry optimization computing module 317 using a geometry optimization algorithm (as described later). The positional information on the initial position of each atom may represent any three-dimensional coordinates.

The energy/force computing module 313 may receive the positional information of each atom as obtained by the obtaining module 311 to calculate the energy (or loss) of the substance of interest. The energy/force computing module 313 may calculate a force fⱼ (where j is an index for identifying each atom of the substance) acting on each atom, by differentiating the energy of the substance of interest with respect to the position of each atom to determine its norm, i.e., by calculating a gradient norm of the energy.

The energy/force computing module 313 calculates the energy of the substance from, for example, the positional information of each atom of the substance. The energy/force computing module 313 can be, for example, implemented by a trained model. The trained model can be, for example, a neural network potential (NNP) model, a density functional theory (DFT) model, or a classical molecular dynamics potential (hereinafter, classical potential) model. For the sake of specificity, the energy/force computing module 313 will be exemplified by a trained NNP model below.

The selector module 315 may select a geometry optimization algorithm for use in the computation by the geometry optimization computing module 317. For example, the selector module 315 selects a geometry optimization algorithm for use in the computation according to the force acting on each one of the atoms included in the substance.

More specifically, the selector module 315 may determine the relationship in magnitude between a maximum value fₘₐₓ of the force fⱼ acting on each atom and a preset threshold fₜₕ to select a geometry optimization algorithm for the computation according to a result of the determination. For example, the geometry optimization computing module 317 performs a geometry optimization of the substance by a first algorithm in the early phase of the iterative computation in the geometry optimization process. In addition, the geometry optimization computing module 317 may perform a geometry optimization of the substance by a second algorithm different from the first algorithm in the final phase of the iterative computation in the geometry optimization process.

Preferably, the first algorithm may be the one with a relatively high degree of robustness in the early phase of the iterative computation in the substance geometry optimization process. The first algorithm can be, for example, a fast inertial relaxation engine (FIRE) algorithm. The second algorithm may be preferably the one with a higher rate of convergence than the first algorithm and less likely to result in NaN (Not a Number) in the final phase of the iterative computation in the substance geometry optimization process. The second algorithm can be, for example, a limited memory Broyden-Fletcher-Goldfarb-Shanno (LBFGS) algorithm.

In the following, the first algorithm will be exemplified by FIRE while the second algorithm will be exemplified by LBFGS for the sake of specificity. However, the first and second algorithms are not limited to such algorithms. Other algorithms (e.g., LBFGS line search) may be adoptable as long as they have the above-described properties.

For example, the selector module 315 compares fₘₐₓ and fₜₕ. When fₘₐₓ>fₜₕ holds, the selector module 315 selects FIRE as a geometry optimization algorithm. When fₘₐₓ≤fₜₕ is found as a result of comparison between fₘₐₓ and fₜₕ, the selector module 315 may select LBFGS as a geometry optimization algorithm.

The geometry optimization computing module 317 may perform a geometry optimization of the substance by the algorithm selected by the selector module 315 in the geometry optimization process. Thus, when fₘₐₓ>fₜₕ holds, the geometry optimization computing module 317 may use FIRE to iteratively compute a step size of coordinates of each atom of the substance for geometry optimization to obtain positional information of each atom representing that the geometry of the substance is at an energy minimum. When fₘₐₓ≤fₜₕ is found as a result of comparison between fₘₐₓ and fₜₕ, the geometry optimization computing module 317 may use LBFGS to iteratively compute a step size of coordinates of each atom of the substance for geometry optimization to obtain positional information of each atom representing that the geometry of the substance is at an energy minimum.

The output module 319 may output, to the main storage 33 and/or the auxiliary storage 35, the substance energy and other results as obtained through the inference process including the geometry optimization process. The output module 319 can also output the substance energy and other results as obtained through the inference process to the external device 9A via the communication network 5.

Inference Process Including Geometry Optimization Process Now, an exemplary inference process to be implemented by the inference device 1 according to an embodiment will be described. This inference process includes a geometry optimization process that uses multiple algorithms in a switchable manner depending on the situation.

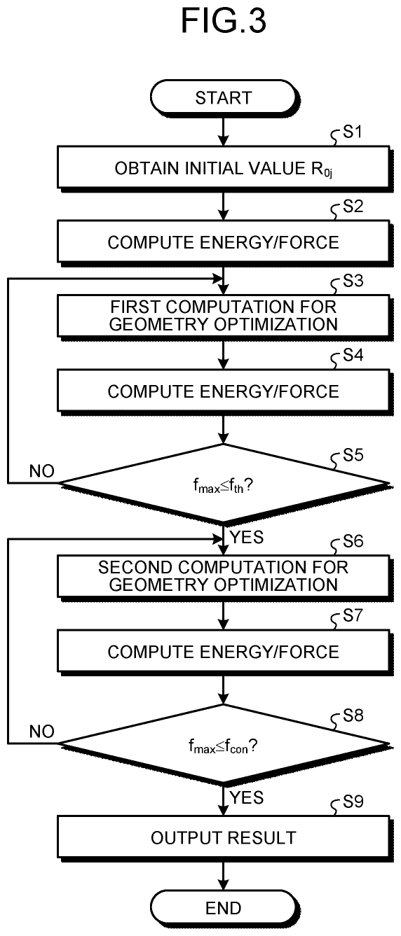

FIG. 3 is a flowchart illustrating the inference process of the present embodiment.

First, the obtaining module 311 may obtain initial positional information (initial value) R₀ⱼ of each atom of a user desired substance (step S1).

Note that the initial value R₀ⱼ obtained at step S1 may be a value retrieved from the main storage 33 or the auxiliary storage 35 or may be obtained from another device via the network interface 37, for example.

The energy/force computing module 313 may receive the positional information R₀ⱼ of each atom obtained by the obtaining module 311 to compute the energy of the substance of interest and the force on each atom (step S2).

The geometry optimization computing module 317 performs a first computation for geometry optimization based on the energy computed by the energy/force computing module 313 at step S2 and the positional information R₀ⱼ to obtain positional information Rᵢⱼ of each atom representing that the geometry of the substance is at an energy minimum (step S3). The first computation for geometry optimization at step S3 may use FIRE as the first algorithm. Also, the first computation for geometry optimization at step S3 may be iteratively, sequentially performed.

The energy/force computing module 313 may receive the positional information Rᵢⱼ of each atom representing that the geometry of the substance is at an energy minimum, to compute energy Eᵢ of the substance of interest and a force fᵢⱼ on each atom (step S4).

The selector module 315 may compare a maximum value fₘₐₓ of the force fᵢⱼ on each atom and a preset threshold fₜₕ (step S5). When fₘₐₓ>fₜₕ (No at step S5), the selector module 315 may select FIRE as the first algorithm for the computation for geometry optimization to perform the first computation for geometry optimization. When fₘₐₓ≤fₜₕ (Yes at step S5), however, the selector module 315 may select LBFGS as the second algorithm for the computation for geometry optimization to perform the second computation for geometry optimization.

The geometry optimization computing module 317 may perform the second computation for geometry optimization by LBFGS using the energy computed by the energy/force computing module 313 at step S4 and the positional information Rᵢⱼ of each atom computed at step S3, to obtain positional information Rᵢ₊₁ⱼ of each atom representing that the geometry of the substance is at an energy minimum (step S6). The second computation for geometry optimization at step S6 may be iteratively, sequentially performed.

The energy/force computing module 313 may receive the positional information Rᵢ₊₁ⱼ of each atom representing that the geometry of the substance is at an energy minimum, to compute energy Eᵢ₊₁ of the substance of interest and a force fᵢ₊₁ⱼ on each atom (step S7).

The selector module 315 may compare a maximum value fₘₐₓ of the force fᵢ₊₁ⱼ on each atom and a preset convergence threshold f_{con} (step S8). When fₘₐₓ>f_{con} (No at step S8), the operations at steps S6 and S7 may be performed again. When fₘₐₓ≤f_{con} (Yes at step S8), however, the selector module 315 may determine the positional information of each atom obtained at step S6 and the energy obtained at step S7 as corresponding to the substance geometry being at an energy minimum.

The output module 319 may output, as a result of the inference, the energy and the positional information determined at step S8 (step S9).

The inference device 1 according to the present embodiment may include at least one memory, i.e., the main storage 33 and the auxiliary storage 35, and at least one processor, i.e., the processor 31. For geometry optimization of the substance, the processor 31 may use the first algorithm (e.g., FIRE) and the second algorithm (e.g., LBFGS) in the early phase and final phase of the iterative computation in the geometry optimization process, respectively.

In this manner, the inference device 1 according to the present embodiment can implement the iterative computation for geometry optimization of the substance at a higher rate of convergence by using the two algorithms than by using FIRE alone. Also, the inference device 1 can implement the iterative computation for geometry optimization of the substance with a higher degree of robustness by using the two algorithms than by using LBFGS alone.

In addition, the processor 31 switches the algorithm, for example, from FIRE to LBFGS depending on the force acting on multiple atoms included in the substance. Specifically, the processor 31 may automatically switch the algorithm from FIRE to LBFGS in response to an event that the maximum value fₘₐₓ of the force acting on the multiple atoms included in the substance matches or falls below the threshold fₜₕ. As such, the processor 31 can perform algorithm switching based on an objective index, achieving stable geometry optimization.

Further, the processor 31 can calculate substance energy using any of a NNP model, a DFT model, and a classical potential model to perform a geometry optimization based on the resultant energy. The processor 31 can thus automatically perform algorithm switching based on an objective index irrespective of the model in use, for example, a DFT model with a relatively high computational load or a NNP model capable of high-speed computing. This results in eliminating the necessity for the user to pay constant attention to the device, making it possible to abate human workload for the geometry optimization process, for example.

### Second Embodiment

Next, an inference device 1 according to a second embodiment will be described. During the second computation for geometry optimization by LBFGS being the second algorithm, the inference device 1 of the second embodiment may switch to the first computation for geometry optimization by FIRE being the first algorithm again when the force applied to the atoms satisfies a predetermined criterion.

Herein, the predetermined criterion refers to, for example, occurrence of oscillation of the second algorithm or a change (for example, a rise) in the force f applied to the atoms from which possible occurrence of oscillation may be inferred. In the present embodiment, the predetermined criterion is defined as an event that fₘₐₓ exceeds a preset threshold fₜₕ (fₘₐₓ>fₜₕ) by way of example.

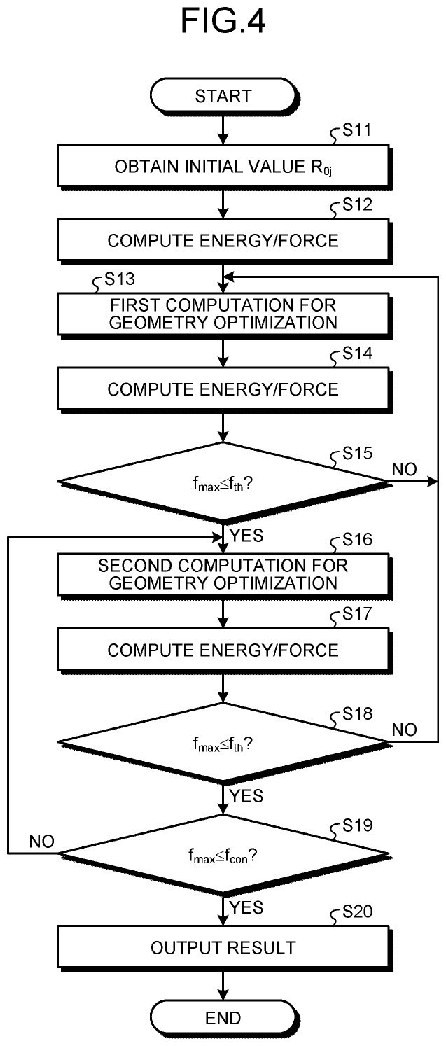

FIG. 4 is a flowchart illustrating an exemplary inference process according to the second embodiment. Steps S11 to S17 in FIG. 4 correspond to steps S1 to S7 in FIG. 3, therefore, a description thereof will be omitted.

The selector module 315 may compare the maximum value fₘₐₓ of the force fᵢⱼ on each atom obtained at step S17 and the preset threshold fₜₕ (step S18). When fₘₐₓ>fₜₕ (No at step S18), the selector module 315 may select FIRE as a geometry optimization algorithm to perform the operations including the first computation for geometry optimization at steps S13 to S17 again. When fₘₐₓ≤fₜₕ (Yes at step S18), however, the flow may proceed to step S19. Note that steps S19 and S20 correspond to steps S8 and S9 in FIG. 3, therefore, a description thereof will be omitted.

Owing to the features described above, the processor 31 can switch LBFGS being the second algorithm to FIRE being the first algorithm for geometry optimization when the maximum value fₘₐₓ of the force on the multiple atoms included in the substance exceeds the threshold fₜₕ.

As such, in a situation that LBFGS fails in assuming a local quadratic approximation and oscillates, for example, the processor 31 can perform a geometry optimization by FIRE again, achieving an improvement in convergence performance.

### Third Embodiment

Next, an inference device 1 according to a third embodiment will be described. During the second computation for geometry optimization by LBFGS being the second algorithm, the inference device 1 of the second embodiment may switch to the first computation for geometry optimization by FIRE being the first algorithm again when the energy of the substance satisfies a predetermined criterion.

Herein, the predetermined criterion refers to, for example, occurrence of oscillation of the second algorithm or a change (for example, a rise) in energy value from which possible occurrence of oscillation may be inferred. In the present embodiment, the predetermined criterion may be defined as an event that the energy Eᵢ in FIG. 3 exceeds a preset threshold Eₜₕ (Eᵢ>Eₜₕ) by way of example. The preset threshold Eₜₕ can be a minimum value of the computed energy Eᵢ.

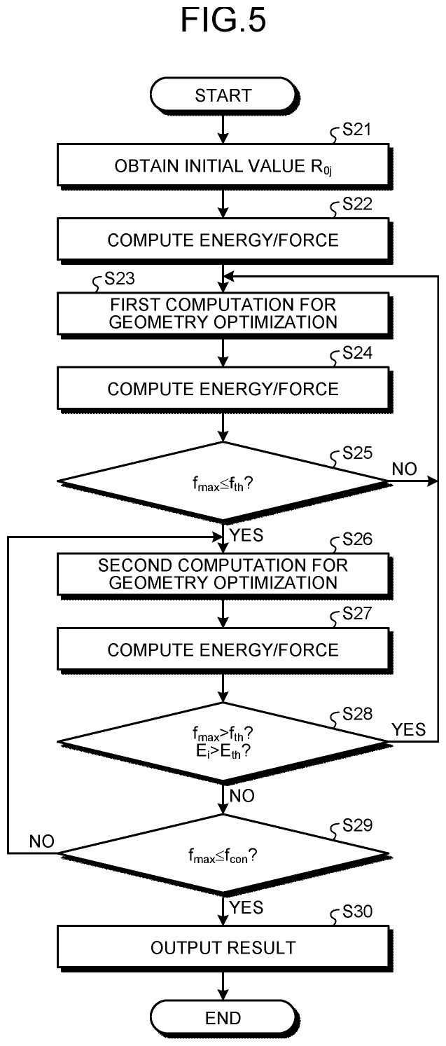

FIG. 5 is a flowchart illustrating an exemplary inference process according to the third embodiment. Steps S21 to S27 in FIG. 5 correspond to steps S1 to S7 in FIG. 3, therefore, a description thereof will be omitted.

The selector module 315 may compare the energy Eᵢ of the substance and the preset threshold Eₜₕ, in addition to the comparison between the maximum value fₘₐₓ of the force fᵢⱼ on each atom and the preset threshold fₜₕ (step S28). When one or both of fₘₐₓ>fₜₕ and Eᵢ>Eₜₕ hold (Yes at step S28), the selector module 315 may select FIRE as the first algorithm for geometry optimization to perform the operations including the first computation for geometry optimization at steps S23 to S27 again. When neither fₘₐₓ>fₜₕ nor Eᵢ>Eₜₕ holds or only one of fₘₐₓ>fₜₕ and Eᵢ>Eₜₕ holds (No at step S28), however, the flow may proceed to step S29.

Note that steps S29 and S30 correspond to steps S8 and S9 in FIG. 3, therefore, a description thereof will be omitted.

Owing to the features as described above, for geometry optimization the processor 31 can switch the second algorithm being LBFGS to the first algorithm being FIRE according to the predetermined condition.

As such, in a situation that reciprocative oscillation between FIRE and LBFGS occurs in the vicinity of the threshold fₜₕ due to presence of a landscape unlike an fₘₐₓ monotonic decrease, for example, the processor 31 can perform a geometry optimization by using FIRE again, achieving an improvement in convergence performance.

### Fourth Embodiment

Now, an inference device 1 according to a fourth embodiment will be described. The inference device 1 according to the fourth embodiment may update the value of fₜₕ serving as a switching criterion (or set the value of fₜₕ to a smaller value), upon every switching from FIRE being the first algorithm to LBFGS being the second algorithm (i.e., switching from the first computation to the second computation for geometry optimization).

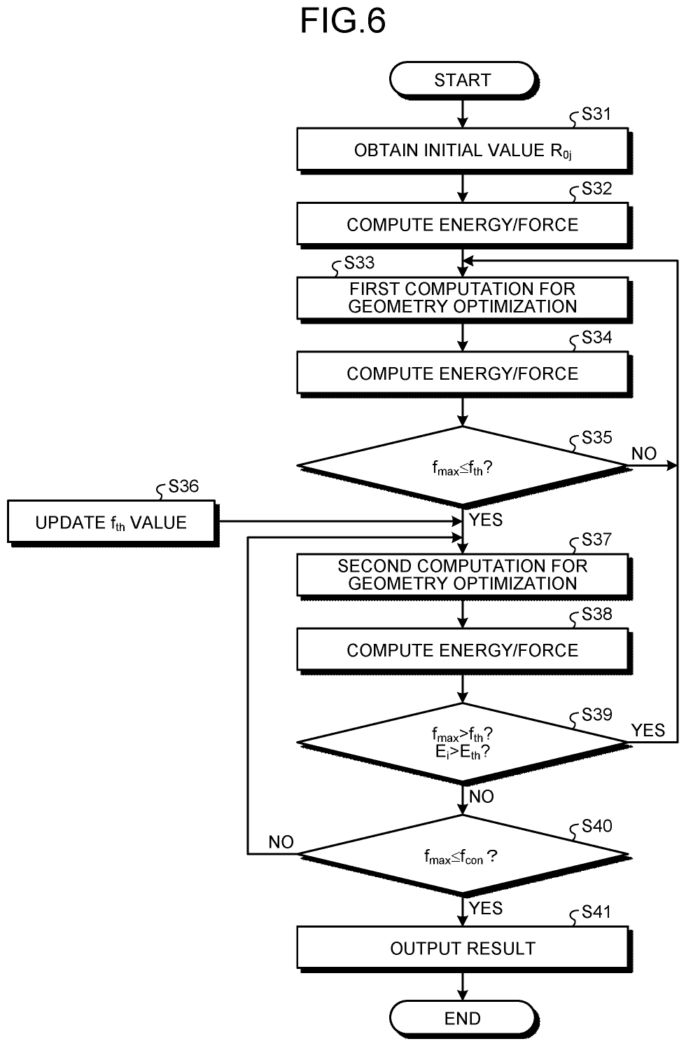

FIG. 6 is a flowchart illustrating an exemplary inference process according to the fourth embodiment. Steps S31 to S35 in FIG. 6 correspond to steps S1 to S5 in FIG. 3, therefore, a description thereof will be omitted.

When fₘₐₓ≤fₜₕ, the selector module 315 may update the fₜₕ value such that the fₜₕ value becomes smaller than the previous value at step S35 (step S36).

Subsequent steps S37 to S41 in FIG. 6 correspond to steps S26 and S30 in FIG. 5, therefore, a description thereof will be omitted.

Owing to the features described above, the processor 31 can lower the threshold value fₜₕ serving as the switching criterion every time it performs switching from FIRE being the first algorithm to LBFGS being the second algorithm.

As such, in a situation that both the energy and the force rise at the initial step of the computation for geometry optimization by LBFGS, which may possibly result in oscillation in algorithm switching, for example, the processor 31 can avoid occurrence of oscillation by lowering the value of the threshold fₜₕ, thereby improving the convergence performance.

To implement the technical idea of an embodiment by an inference method, the method may include performing a geometry optimization of a substance by a first algorithm in the early phase of iterative computation in a geometry optimization process and performing a geometry optimization of the substance by a different, second algorithm in the final phase of the iterative computation.

To implement the technical idea of an embodiment by a decision-making computer program, the computer program may include instructions to cause one or more computers to perform a geometry optimization of a substance by a first algorithm in the early phase of iterative computation in a geometry optimization process and performing a geometry optimization of the substance by a different, second algorithm in the final phase of the iterative computation.

For example, an optimal-parameter determining process can be implemented by installing the decision-making computer program on a computer and loading that into the memory in any analytical device or analytical server that analyzes energy and/or force of an atomic structure including multiple atoms. Such a computer program including instructions to cause the computer to execute the process can be stored and distributed in a storage medium such as a magnetic disk (e.g., hard disk), an optical disk (e.g., CD-ROM, DVD), or a semiconductor memory. The procedures and effects of the optimal-parameter determining process by the decision-making computer program are the same as or similar to those of the embodiments, therefore, a description thereof is omitted.

A part or all of the respective devices in any of the above-described embodiments may be configured by hardware, or may be configured by information processing of software (program) executed by a central processing unit (CPU), a graphics processing unit (GPU), or the like. When configured by information processing by software, the information processing of software may be executed by storing software that implements at least part of the functions of the respective devices of any of the above-described embodiments in a non-transitory storage medium (non-transitory computer readable medium) such as a flexible disk, a compact disc-read only memory (CD-ROM), and a universal serial bus (USB) memory and causing the computer 3 to read the software. Furthermore, the software may be downloaded via the communication network 5. Moreover, the information processing may be executed by hardware by the software being implemented in circuitry such as an application specific integrated circuit (ASIC) or a field programmable gate array (FPGA).

The type of a storage medium that stores the software is not limited to a particular type. The storage medium is not limited to a removable storage medium such as a magnetic disk and an optical disk, and may be a stationary storage medium such as a hard disk or a memory. Furthermore, the storage medium may be provided inside the computer or outside the computer.

In the present specification (including claims), an expression “at least one of a, b, and c” or “at least one of a, b, or c” (including similar expressions) includes any of a, b, c, a-b, a-c, b-c, and a-b-c. Furthermore, a plurality of instances may be included for any element, such as a-a, a-b-b, and a-a-b-b-c-c. Moreover, an element other than listed elements (a, b, and c), such as d of a-b-c-d, may be added.

In the present specification (including claims), expressions such as “data as input/based on data/in accordance with/in response to” (including similar expressions) include a case where various pieces of data are used as input and a case where various pieces of data subjected to some kind of processing (e.g., noise added data, normalized data, and intermediate expressions of various pieces of data) are used as input, unless otherwise specified. Furthermore, when it is described that some kind of result is obtained “based on/in accordance with/in response to data”, a case where the result is obtained based only on the data is included, and a case where the result is obtained under the influence of other data, factors, conditions, and/or states other than the data may be also included. Furthermore, when it is described that “data is output”, a case where various pieces of data are used as output and a case where various pieces of data subjected to some kind of processing (e.g., noise added data, normalized data, and intermediate expressions of various pieces of data) are used as output are included, unless otherwise specified.

In the present specification (including claims), the terms “connected” and “coupled” are intended as non-limiting terms including all of direct connection/coupling, indirect connection/coupling, electrical connection/coupling, communicative connection/coupling, operative connection/coupling, physical connection/coupling, and the like. The terms should be appropriately interpreted in accordance with the context in which the terms are used. Connection/coupling forms which are not intentionally or naturally excluded should be interpreted in a non-limiting manner as being included in the terms.

In the present specification (including claims), an expression “A configured to B” may include that the physical structure of the element A has a configuration capable of executing the operation B, and that a permanent or temporary setting/configuration of the element A is configured/set to actually execute the operation B. For example, when the element A is a general-purpose processor, the processor may have a hardware configuration capable of executing the operation B, and the processor is only required to be configured to actually execute the operation B by permanent or temporary program (command) setting. Furthermore, when the element A is a dedicated processor, dedicated arithmetic circuitry, and the like, the circuitry structure of the processor is only required to be implemented to actually execute the operation B regardless of whether or not a control command and data are actually attached.

In the present specification (including claims), terms meaning inclusion or possession (e.g., “comprising/including” and “having”) are intended as open-ended terms including a case where objects other than targets indicated by objects of the terms are included or possessed. When an object of a term meaning inclusion or possession is an expression that does not designate number and quantity or an expression that suggests a singular number (expression with article “a” or “an”), the expression should be interpreted as not being limited to a specific number.

In the present specification (including claims), even if an expression such as “one or more” or “at least one” is used in one part and an expression that does not designate number and quantity or an expression that suggests a singular number (expression with article “a” or “an”) is used in another part, the latter expression is not intended to mean “one”. In general, the expression that does not designate number and quantity or the expression that suggests a singular number (expression with article “a” or “an”) should be interpreted as not necessarily being limited to a specific number.

In the present specification, when it is described that a specific effect (advantage/result) is obtained in a specific configuration of a certain embodiment, it should be understood that the effect is obtained in one or a plurality of other embodiments having the configuration unless there is some special reason. Note, however, that it should be understood that the presence or absence of the effect generally depends on various factors, conditions, and/or states, and that the effect is not necessarily obtained by the configuration. The effect is merely obtained by the configuration described in an embodiment when various factors, conditions, and/or states are satisfied. The effect is not necessarily obtained in the invention according to claims in which the configuration or a similar configuration is specified.

In the present specification (including claims), terms such as “maximize” include determining a global maximum, determining an approximation of the global maximum, determining a local maximum, and determining an approximation of the local maximum, and should be appropriately interpreted depending on the context in which the terms are used. Furthermore, stochastically or heuristically determining an approximation of the maximum is included. Similarly, terms such as “minimize” include determining a global minimum, determining an approximation of the global minimum, determining a local minimum, and determining an approximation of the local minimum, and should be appropriately interpreted depending on the context in which the terms are used. Furthermore, stochastically or heuristically determining an approximation of the minimum is included. Similarly, terms such as “optimize” include determining a global optimum, determining an approximation of the global optimum, determining a local optimum, and determining an approximation of the local optimum, and should be appropriately interpreted depending on the context in which the terms are used. Furthermore, stochastically or heuristically determining an approximation of the optimum is included.

In the present specification (including claims), to perform certain processing by multiple pieces of hardware, the pieces of hardware may perform the processing in cooperation or part of the hardware may perform the entire processing. Alternatively, part of the hardware may perform part of the processing while another part of the hardware may perform the rest of the processing. In the present specification (including claims), an expression such as “one or more pieces of hardware perform first processing and the one or more pieces of hardware perform second processing”, if used, may signify that the hardware that performs first processing and the hardware that performs second processing may be the same or different from each other. In other words, the hardware that performs first processing and the hardware that performs second processing may only be included in the one or more pieces of hardware. Such hardware may include electronic circuitry or a device including electronic circuitry.

In the present specification (including claims), when multiple storages (memory) store data, the individual storages may store only part of the data or the data as a whole.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

1. An inference device, comprising:
at least one memory; and
at least one processor configured to:
perform a first geometry optimization of a substance by a first algorithm, and
after a predetermined condition is satisfied, perform, based on a result of the first geometry optimization by the first algorithm, a second geometry optimization of the substance by a second algorithm different from the first algorithm.

2. The inference device according to claim 1, wherein
the predetermined condition is determined based on a force acting on a plurality of atoms included in the substance.

3. The inference device according to claim 2, wherein
the predetermined condition is such that a maximum value of the force acting on the plurality of atoms included in the substance matches or falls below a predetermined threshold.

4. The inference device according to claim 3, wherein
the at least one processor is further configured to perform the first geometry optimization of the substance by the first algorithm based on a result of the second optimization by the second algorithm, when the maximum value of the force acting on the plurality of atoms included in the substance exceeds the predetermined threshold.

5. The inference device according to claim 4, wherein
the predetermined threshold is updated after the first algorithm is changed to the second algorithm.

6. The inference device according to claim 1, wherein
the predetermined condition is determined based on energy of the substance.

7. The inference device according to claim 6, wherein
the predetermined condition is such that a maximum value of the energy matches or falls below a predetermined threshold.

8. The inference device according to claim 1, wherein
the at least one processor is further configured to use a fast inertial relaxation engine (FIRE) algorithm as the first algorithm and use a limited memory Broyden-Fletcher-Goldfarb-Shanno (LBFGS) algorithm as the second algorithm.

9. The inference device according to claim 1, wherein
the at least one processor is further configured to:
compute energy of the substance by using any of a neural network potential model, a density functional theory model, and a classical potential model.

10. The inference device according to claim 1, wherein
the second algorithm is higher in rate of convergence than the first algorithm.

11. The inference device according to claim 1, wherein
the at least one processor is further configured to iteratively perform the first and second geometry optimization of the substance.

12. The inference device according to claim 1, wherein
the result of the first geometry optimization by the first algorithm includes at least information on a structure of the substance.

13. The inference device according to claim 1, wherein
after the predetermined condition is not satisfied, the at least one processor is further configured to perform, based on the result of the first geometry optimization by the first algorithm, the first geometry optimization of the substance by the first algorithm.

14. An inference method, comprising:
performing, by at least one processor, a first geometry optimization of a substance by a first algorithm, and
after a predetermined condition is satisfied,
performing, by the at least one processor, based on a result of the first geometry optimization by the first algorithm, a second geometry optimization of the substance by a second algorithm different from the first algorithm.

15. The inference method according to claim 14, wherein
the predetermined condition is determined based on a force acting on a plurality of atoms included in the substance.

16. The inference method according to claim 14, wherein
the predetermined condition is such that a maximum value of the force acting on the plurality of atoms included in the substance matches or falls below a predetermined threshold.

17. The inference method according to claim 16, further comprising:
performing, the at least one processor, the first geometry optimization of the substance by the first algorithm based on a result of the second geometry optimization by the second algorithm, when the maximum value of the force acting on the plurality of atoms included in the substance exceeds the predetermined threshold.

18. The inference method according to claim 14, wherein
the predetermined threshold is updated after the first algorithm is changed to the second algorithm.

19. The inference method according to claim 14, wherein
the predetermined condition is determined based on energy of the substance.

20. The inference method according to claim 14, further comprising:
after the predetermined condition is not satisfied, performing, the at least one processor, based on the result of the first geometry optimization by the first algorithm, the first geometry optimization of the substance by the first algorithm.
